(19) United States
(12) Patent Application Publication
(10) Pub. No.: US 2026/0312845 A1
(43) Pub. Date: Oct. 8, 2026

(54) SIGNAL GENERATOR SYSTEM

(71) Applicant: Rohde & Schwarz GmbH & Co. KG, Muenchen (DE)

(72) Inventors: Tim BENNECKENSTEIN, Muenchen (DE); Simon SCHOLL, Muenchen (DE); Robert VIELHUBER, Muenchen (DE); Nico FALK, Muenchen (DE)

(21) Appl. No.: 19/098,248

(22) Filed: Apr. 2, 2025

(51) Int. Cl. H04L 25/03; H04B 1/04; H04L 5/00

(52) U.S. Cl. CPC H04L 25/03834; H04B 1/0475; H04L 5/0044

(57) ABSTRACT

A signal generator system for generating a radio frequency signal is described. The signal generator system includes at least one data input, at least one control input, and a waveform processing circuit. The at least one data input is configured to receive at least one waveform data stream, the at least one waveform data stream including information on a waveform to be generated. The at least one control input is configured to receive at least one control command signal, the control command signal including control information for modifying the data stream. The at least one waveform processing circuit is configured to modify the at least one waveform data stream based on the control command signal, thereby obtaining at least one modified waveform data stream.

### FIELD OF THE DISCLOSURE

Embodiments of the present disclosure generally relate to a signal generator system for generating a radio frequency (RF) signal.

### BACKGROUND

The generation and manipulation of radio frequency (RF) signals plays a critical role in various applications such as radar systems, direction finding systems, and communication systems.

For performing tests on such systems, accurately emulating the environmental conditions, as well as positions and/or movements of signal sources is essential for effective testing and validation. Existing solutions often involve static recordings or require significant post-processing to apply necessary modifications. These solutions may be time-consuming and computationally expensive, which may make existing solutions inadequate for real-time applications.

Thus, there is a need for a signal generator system that provides improved possibilities to alter the RF signal for testing purposes.

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a signal generator system for generating a radio frequency (RF) signal. In an embodiment, the signal generator system comprises at least one data input, at least one control input, and a waveform processing circuit. The data input is configured to receive at least one waveform data stream, the at least one waveform data stream comprising information on a waveform to be generated. The at least one control input is configured to receive at least one control command signal, the control command signal comprising control information for modifying the data stream. The at least one waveform processing circuit is configured to modify the at least one waveform data stream based on the control command signal, thereby obtaining at least one modified waveform data stream.

The signal generator system according to embodiments of the present disclosure is based on the idea to provide dynamic real-time adjustments of high-volume data streams.

While previously known approaches may rely on offline methodologies to provide specific measurement scenarios, the disclosed signal generator systems enable continuous waveform modifications on-the-fly, thereby reducing the latency and complexity typically associated with emulating measurement scenarios.

By performing real-time data manipulation of the waveform data stream, the disclosed signal generator systems enables complex testing scenarios for a plurality of different devices under test, which may not be achievable via previously known methods.

In one embodiment, by dynamically adjusting parameters such as amplitude, frequency, and phase without halting the data stream, a multitude of application possibilities are achieved. For example, the signal generator systems disclosed herein supports direction finding tests, phased-array assessments, and various hardware-in-the-loop evaluations that require synchronized, high-volume signal recordings.

As a result, the signal generator systems disclosed herein not only streamlines experimentation, testing, and validation procedures, but also ensure higher fidelity of the measurements, thereby delivering more reliable results than what is conventionally attainable.

According to an aspect of the present disclosure, the waveform data stream is, for example, an IQ-data stream. Accordingly, the waveform data stream comprises in-phase (I) data and quadrature (Q) data relating to the waveform to be generated. The use of an IQ data stream in the signal generator system enables more precise control over phase and amplitude, thereby improving signal quality.

In an example embodiment, the signal generator system comprises at least one RF frontend. The at least one RF frontend, for example, is configured to generate at least one RF transmission signal. In one embodiment, the at least one RF frontend may be configured to up-convert the frequency of the at least one modified waveform data stream to a predefined frequency that is appropriate for performing a corresponding measurement on a device under test, thereby obtaining the at least one RF transmission signal.

In one embodiment, the at least one RF frontend may be configured to up-convert the frequency of the at least one modified waveform data stream by mixing the at least one RF transmission signal with a local oscillator signal having a predefined frequency.

According to another aspect of the present disclosure, the signal generator system further comprises, for example, an RF output interface. In an embodiment, the RF output interface is connectable to at least one RF antenna and/or to a device under test.

Accordingly, the at least one RF transmission signal may be transmitted over the air via the at least one RF antenna, e.g. to the device under test, such that the device under test can be tested over the air.

In an embodiment, the at least one RF antenna may comprise a single RF antenna, a plurality of RF antennas, and/or an RF antenna array.

Alternatively, the device under test can be connected directly to the RF output interface, such that the at least one RF transmission signal may be transmitted to the device under test via a wire-based connection, thereby enabling hardware-in-the-loop (HIL) testing of the device under test.

For example, the at least one RF transmission signal may correspond to an emulated signal that would be received by at least one receiver antenna connected to the device under test. This enables, for example, to test an analysis circuit of the device under test such as a direction finding system without the corresponding receiver antennas being necessary.

In an embodiment, the signal generator system may further comprise at least one sample memory being connected to the at least one data input, wherein the at least one sample memory is configured to store the waveform data stream received via the data input. The sample memory allows for (temporary) local storage of the incoming waveform data stream, thereby enhancing the resilience to latencies in the waveform data stream. In other words, the at least one sample memory may be configured as a buffer memory.

It also conceivable that different waveform data streams may be stored in the at least one sample memory, which allows for a seamless switching between the different waveform data streams for performing tests associated with different testing scenarios.

In an embodiment, the at least one sample memory may be a non-transient memory.

As another example, the at least one sample memory may be a temporary memory such as a random access memory.

In another example embodiment, the signal generator system is configured to generate at least two different modified waveform data streams. As will be described in more detail below, this drastically increases the number of testing scenarios that can be emulated via the signal generator system according to the present disclosure.

For example, the at least two different modified waveform data streams may correspond to different aspects of a testing scenario, such as different signal sources moving at different speeds and/or in different directions, multiple signal sources being arranged at different positions, and/or multiple receiver antennas being arranged at different positions.

According to an aspect of the present disclosure, the signal generator system is configured, for example, to generate the at least two different modified waveform data streams independent of each other. Thus, different testing scenarios and/or different aspects of a testing scenario can be emulated independent of each other.

According to a further aspect of the present disclosure, the at least two different modified waveform data streams correspond, for example, to the same waveform data stream. Accordingly, different testing scenarios and/or different aspects of a testing scenario can be emulated based on the same waveform data stream. Thus, it is not necessary to provide different waveform data streams for each testing scenario or each aspect of a testing scenario, which significantly reduces the data bandwidth required by the signal generator system according to the present disclosure.

Another aspect of the present disclosure provides that the at least two different modified waveform data streams correspond, for example, to different waveform data streams. This allows to perform emulations of complex testing scenarios and/or seamless switching between different testing scenarios.

In an example embodiment, the at least one waveform data stream comprises a recorded waveform. Accordingly, the signal generator system adapts the previously recorded waveform in order to emulate certain different testing scenarios, instead of having to record appropriate waveforms for each different testing scenario.

For example, the waveform may be recorded using at least one RF antenna, for example a plurality of RF antennas or an RF antenna array.

According to an aspect of the present disclosure, the at least one data input comprises, for example, at least one Ethernet port. Accordingly, the at least one waveform data stream may be transmitted, received and processed based on the Ethernet standard, which ensures reliable data transmission at high bandwidths. Moreover, as Ethernet is a common standard used in a multitude of different computer systems, this ensures maximum compatibility with different computer systems.

In one embodiment, the at least one data input may be configured to receive the at least one waveform data stream via an Ethernet UDP stack. This allows for a particularly high data bandwidth with particularly low latency, thereby enabling fast and reliable transfer of large data volumes.

An aspect of the present disclosure provides that the at least one waveform data stream has, for example, a first bandwidth. In an embodiment, the at least one waveform processing circuit is configured to separate the at least one waveform data stream into a plurality of waveform data sub-streams, wherein each waveform data sub-stream has a bandwidth being a sub-band of the first bandwidth. Accordingly, the different sub-bands of the waveform data stream can be processed individually, which provides even more flexibility for emulating testing scenarios.

In an embodiment, the individual waveform data sub-streams may be manipulated or modified in the same manner or in different manners.

In an embodiment, the individual waveform data sub-streams may be manipulated or modified independent of each other.

For example, the different waveform data sub-streams may correspond to different aspects of a testing scenario, such as different signal sources and/or different receiver antennas being emulated.

In another embodiment, the at least one waveform processing circuit is configured to separate the at least one waveform data stream into a plurality of waveform data sub-streams, wherein the at least one waveform processing circuit is configured to generate a plurality of modified waveform data streams based on the plurality of waveform data sub-streams.

In an embodiment, the RF frontend described above may be configured to generate a plurality of RF transmission signals based on the plurality of modified waveform data sub-streams.

In an embodiment, the plurality of modified waveform data streams, and thus the plurality of RF transmission signals may correspond to different aspects of a testing scenario, such as different objects, an environment of the objects, different signal sources, different receiver antennas, atmospheric distortions, etc. Accordingly, a plurality of aspects of the testing scenario can be emulated simultaneously by the signal generator system according to the present disclosure.

Alternatively or additionally, the plurality of plurality of modified waveform data streams, and thus the plurality of RF transmission signals may correspond to different testing scenarios, which allows for a seamless switching between the different testing scenarios.

In an embodiment, the signal generator system may comprise a plurality of RF outputs, wherein the signal generator system is configured to output a plurality of RF transmission signals corresponding to the plurality of modified waveform data streams via the plurality of RF outputs. In one embodiment, the plurality of RF outputs may be part of the RF output interface described above.

Accordingly, the plurality of RF transmission signals may be transmitted over the air via the at least one RF antenna, e.g. to the device under test, such that the device under test can be tested over the air.

In an embodiment, the at least one RF antenna may comprise a single RF antenna, a plurality of RF antennas, and/or an RF antenna array.

Alternatively, the device under test can be connected directly to one or several of the plurality of RF outputs, such that at least one of the plurality of RF transmission signals may be transmitted to the device under test via a wire-based connection, thereby enabling hardware-in-the-loop (HIL) testing of the device under test.

It is also conceivable that multiple devices under test may be connected to different RF outputs, such that simultaneous testing of multiple devices under test is enabled.

In an embodiment, the signal generator system may comprise a summation circuit, wherein the summation circuit is configured to sum at least two of the plurality of modified waveform data streams. Accordingly, the resulting summed modified waveform data stream may comprise different events or different aspects of a testing scenario, wherein the individual aspects may correspond to the individual modified waveform data streams before summation.

In an embodiment, the summation circuit may be configured to sum each modified waveform data stream of the plurality of modified waveform data streams.

In an embodiment, the waveform data stream comprises at least one fading parameter. This enables particularly realistic emulation of testing scenarios.

According to an aspect of the present disclosure, the control command signal, for example, corresponds to a predefined test scenario for a device under test. Accordingly, the waveform data stream is adapted or modified to correctly emulate the predefined test scenario based on the control command signal.

In other words, the same waveform data stream can be adapted to emulate different test scenarios by providing the appropriate control command signal for the respective test scenario.

In an embodiment, the control command signal has a substantially smaller data volume than the waveform data stream. Thus, different test scenarios can be emulated by the signal generator system according to the present disclosure with substantially less data bandwidth required.

In an embodiment, the predefined test scenario may comprise at least one of a radar test, an angle of arrival system test, or a phased antenna array test. Thus, the signal generator system according to the present disclosure allows for testing a large variety of different devices under test.

In another embodiment, the control command signal comprises information on at least one of frequency changes to be applied to the at least one waveform data stream, amplitude changes to be applied to the at least one waveform data stream, or phase changes to be applied to the at least one waveform data stream. By applying these changes to the waveform data stream, test scenarios for testing a device under test can be emulated precisely

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a signal generator system according to an embodiment of the present disclosure;

FIG. 2 schematically shows a test and/or measurement instrument of the signal generator system of FIG. 1;

FIG. 3 schematically shows an embodiment of a waveform processing circuit of the test and/or measurement instrument of FIG. 2;

FIG. 4 schematically shows an embodiment of a portion of the test and/or measurement instrument of FIG. 2; and

FIG. 5 schematically shows another embodiment of a portion of the test and/or measurement instrument of FIG. 2.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

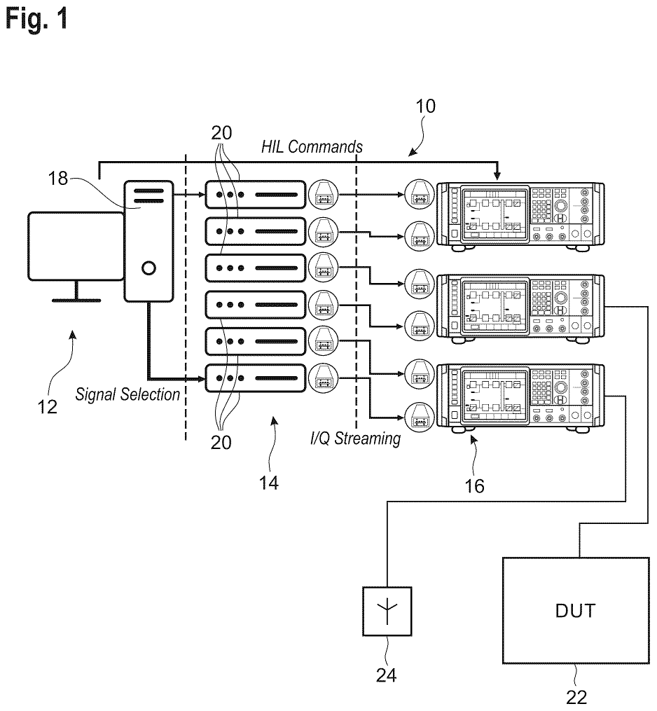

FIG. 1 schematically shows a signal generator system 10 for generating a radio frequency (RF) signal. The signal generator system 10 comprises at least one control circuit 12, a data storage 14, and at least one test and/or measurement instrument 16.

In the example embodiment shown in FIG. 1, the at least one control circuit 12 is implemented into a computer device 18. For example, the computer device 18 may be a personal computer, a MAC, a laptop, a notebook, a smartphone, or any other suitable type of smart device.

In an embodiment, the data storage 14 may be established as a cloud storage that is established by a plurality of servers 20. Additionally or alternatively the data storage 14 may also be established as a local data storage, such as a hard drive or a plurality of hard drives.

In general, waveform data is stored in the data storage 14, which may correspond to a recorded waveform, for example a plurality of recorded waveforms. The waveform data may be saved as IQ-data, i.e. the waveform data may comprise in-phase data and quadrature data relating to the stored waveforms.

The at least one test and/or measurement instrument 16 may be established as at least one signal generator device, such as a signal generator, a vector signal generator, or an arbitrary waveform generator.

In general, the signal generator system 10 is configured to generate at least one RF transmission signal based on at least one waveform data stream in order to perform tests and/or measurements on a device under test (DUT) 22 corresponding to a predefined testing scenario. For example, the at least one control circuit 12 selects the testing scenario for testing the device under test 22, and the corresponding waveform(s) being necessary for performing the corresponding tests.

For example, the control circuit 12 may select the testing scenario based on a user input received via a suitable user interface. As another example, the control circuit 12 may select the testing scenario automatically, e.g. according to a testing routine for the device under test 22. In an embodiment, the testing scenario may comprise several aspects, such as different objects, an environment of the objects, different signal sources, movements of the objects, movements of the signal sources, different receiver antennas capturing a signal, atmospheric distortions, etc.

In an embodiment, the control circuit 12 determines which adjustments to the stored waveform(s) are necessary in order to perform the tests and generates a corresponding control command signal that is forwarded to the at least one test and/or measurement instrument 16 (see “HIL Commands” in FIG. 1).

In an embodiment, the at least one control circuit 12 controls the data storage 14 to stream the selected waveform(s) to the at least one test and/or measurement instrument 16, namely as at least one waveform data stream being an IQ-data stream.

In an embodiment, the at least one test and/or measurement instrument 16 is configured to receive the at least one waveform data stream from the data storage 14. The test and/or measurement instrument 16 further is configured to generate at least one RF transmission signal that is to be applied to the device under test 22 based on the at least one waveform data stream received and based on the control command signal received, as will be described in more detail below.

As is schematically illustrated in FIG. 1, the device under test 22 may be connected to the at least one test and/or measurement instrument 16 via a wire-based connection. Accordingly, the at least one RF transmission signal may be applied to the device under test 22 via the wire-based connection.

Alternatively or additionally, the signal generator system 10 may comprise at least one RF antenna 24 that is connected the at least one test and/or measurement instrument 16 and that allows for testing the device under test 22 over the air.

In an embodiment, the at least one RF antenna 24 may be a single RF antenna, a plurality of RF antennas, or an RF antenna array. In one embodiment, the at least one RF antenna 24 may be part of a test setup that may comprise other equipment such as an anechoic chamber, a variable holder for the device under test 22, reflectors, absorbers, etc.

In general, the at least one waveform selected by the at least one control circuit depends on the type of the device under test 22, i.e. different waveforms may be selected for testing different types of devices under test. In an embodiment, the device under test 22 may be, for example, a radar device, a direction finding device, a phased antenna array, or an angle of arrival system, for example an angle of arrival system for a Traffic Alert and Collision Avoidance System (TCAS). However, it is to be understood that the device under test 22 may be any type of device that can be tested by applying an RF signal.

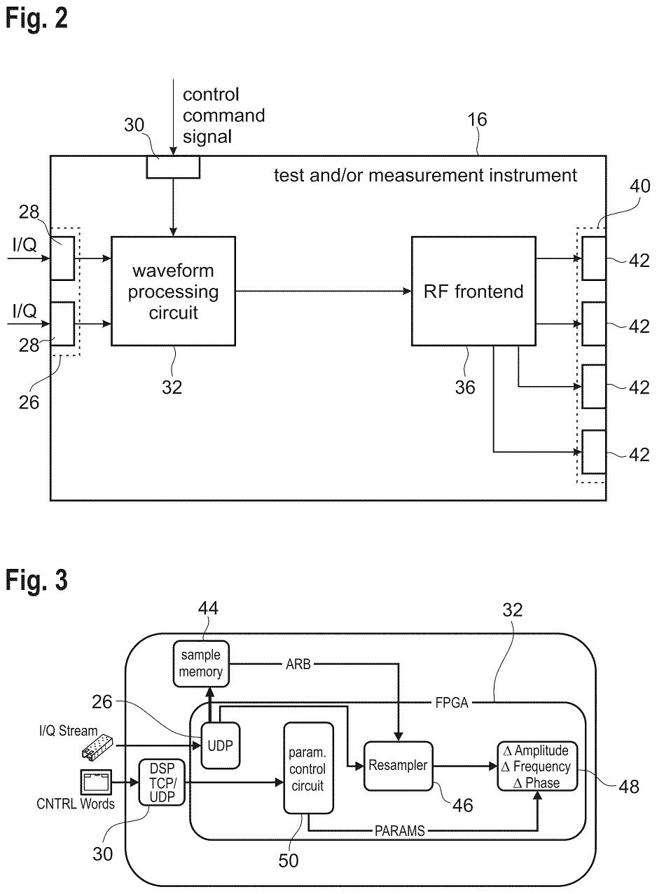

FIG. 2 schematically shows an example of one of the test and/or measurement instruments 16 in more detail. As shown in the example of FIG. 2, the test and/or measurement instrument 16 comprises a data input interface 26 that has at least one data input 28 being configured to receive the at least one waveform data stream from the data storage 14. Therein, the data input interface 26 is connected to the data storage 14, for example via the Internet, via a wide area network, or via a local area network.

In the embodiment shown in FIG. 2, the data input interface 26 comprises two data inputs 28. However, it is to be understood that the data input interface 26 may comprise any other number of data inputs 28, such as one, four, six, eight, etc.

In an embodiment, the data inputs 28 may be established as an Ethernet port, respectively. In one embodiment, the data input interface 26 may be established as a Quad Small Form-factor Pluggable (QSFP) interface.

In an embodiment, the test and/or measurement instrument 16 further comprises at least one control input 30 that is connected to the at least one control circuit 12. The at least one control input 30 is configured to receive the control command signal from the at least one control circuit 12. In an embodiment, the at least one control input 30 may be established as any suitable type of input, for example as an Ethernet port.

In an embodiment, the test and/or measurement instrument 16 further comprises a waveform processing circuit 32 that is connected to both the data input interface 26 and the control input 30 so as to receive the at least one waveform data stream. In general, the waveform processing circuit 32 is configured to modify the at least one waveform data stream based on the control command signal, thereby obtaining at least one modified waveform data stream.

As already mentioned above, the at least one waveform data stream comprises IQ-data relating to at least one waveform to be generated. Accordingly, the at least one modified waveform data stream comprises modified IQ-data that describes the at least one waveform to be generated, but adapted according to the predefined testing scenario. For example, an amplitude, a phase, and/or a frequency of waveform represented by the IQ-data may be adapted to obtain the modified IQ-data.

With these modifications, different aspects of the testing scenario can be emulated correctly, such as Doppler effect, fading, multi-propagation of signals, external distortions, multiple signal sources, multiple receivers, etc.

In an embodiment, the waveform processing circuit 32 may be implemented on an FPGA.

In an embodiment, the test and/or measurement instrument 16 comprises an RF frontend 36 that is arranged downstream of the waveform processing circuit 32. In general, the RF frontend 36 is configured to generate at least one RF transmission signal based on the at least one modified waveform data stream.

Therein, the RF frontend 36 may be configured to up-convert a frequency of the at least one modified waveform data stream to a frequency being suitable for performing tests on the device under test 22, thereby obtaining the at least one RF transmission signal. Any suitable type of RF frontend known in the state of the art may be used. In an embodiment, the RF frontend 36 may comprise at least one digital-to-analog converter being configured to convert the at least one modified waveform data stream into an analog signal.

In an embodiment, the test and/or measurement instrument 16 further comprises an RF output interface 40 that comprises at least one RF output 42. The RF output interface 40 is connected to the RF frontend 36, such that the at least one RF transmission signal is forwarded to the at least one RF output 42.

In the embodiment shown in FIG. 2, the RF output interface 40 comprises a plurality of RF outputs 42. However, it is to be understood that the RF output interface 40 may comprise an arbitrary number of RF outputs 42.

In an embodiment, the RF frontend 36 may be configured to selectively forward the at least one up-converted RF transmission signal to the plurality of RF outputs 42.

In an embodiment, the RF output interface 40, or more precisely the individual RF outputs 42, may be connected to the device under test 22 and/or to the at least one RF antenna 24, such that the at least one RF transmission signal is forwarded to the device under test 22 and/or to the at least one RF antenna 24.

FIG. 3 shows a portion of the test and/or measurement instrument 16 comprising the waveform processing circuit 32 in more detail. As is shown in FIG. 3, the test and/or measurement instrument 16 may further comprise a sample memory 44 that is connected to the data input interface 26. The sample memory 44 is configured to store the at least one waveform data stream received via the data input interface 26 at least temporarily.

In an embodiment, the sample memory 44 may be a non-transient memory. As another example, the sample memory 44 may be a temporary memory such as a random access memory.

In an embodiment, the waveform processing circuit 32 comprises a resampling circuit 46, a modification circuit 48, and a parameter control circuit 50. In the embodiment shown in FIG. 3, the resampling circuit 46 is connected to both the data input interface 26, and to the sample memory 44.

In an embodiment, the at least one waveform data stream received by the data input interface 26 may comprise information on the sample rate of the at least one waveform data stream. The information on the sample rate may be transmitted from the data input interface 26 to the resampling circuit 46.

In an embodiment, the resampling circuit 46 may receive the at least one waveform data stream from the sample memory 44. The resampling circuit 46 is configured to adapt a sample rate of the at least one waveform data stream by resampling the at least one waveform data stream, wherein the sample rate may be increased or decreased.

In one embodiment, the resampling circuit 46 may be configured to resample the at least one waveform data stream based on the information on the sample rate received from the data input interface 26. Alternatively or additionally, the resampling circuit 46 may be configured to resample the at least one waveform data stream based on a target sample rate needed by the at least one digital-to-analog-converter of the RF frontend 36, such that the resampled at least one waveform data stream has the target sample rate.

In one embodiment, a resampling factor applied by the resampling circuit 46 may be configured based on the information on the sample rate received from the data input interface 26, and based on the target sample rate.

In an embodiment, the resampled at least one waveform data stream is forwarded to the modification circuit 48.

In an embodiment, the parameter control circuit 50 is connected to the control input 30 so as to receive the control command signal. In general, the control command signal comprises information on the modifications to the applied to the at least one waveform data stream in order to correctly emulate the testing scenario selected by the control circuit 12. For example, the control command signal may comprise control words indicating the modifications to be applied to the at least one waveform data stream.

Based on the control command signal, the parameter control circuit 50 generates a parameter control signal that comprises information on how signal parameters need to be adapted. The signal parameters to be adapted may comprise an amplitude, a phase, and/or a frequency.

The parameter control signal is forwarded to the modification circuit 48. The modification circuit 48 is configured to modify the resampled at least one waveform data stream based on the parameter control signal, thereby obtaining the at least one modified waveform data stream. More precisely, the modification circuit 48 may adapt the amplitude, phase, and/or frequency of the resampled at least one waveform data stream based on the parameter control signal.

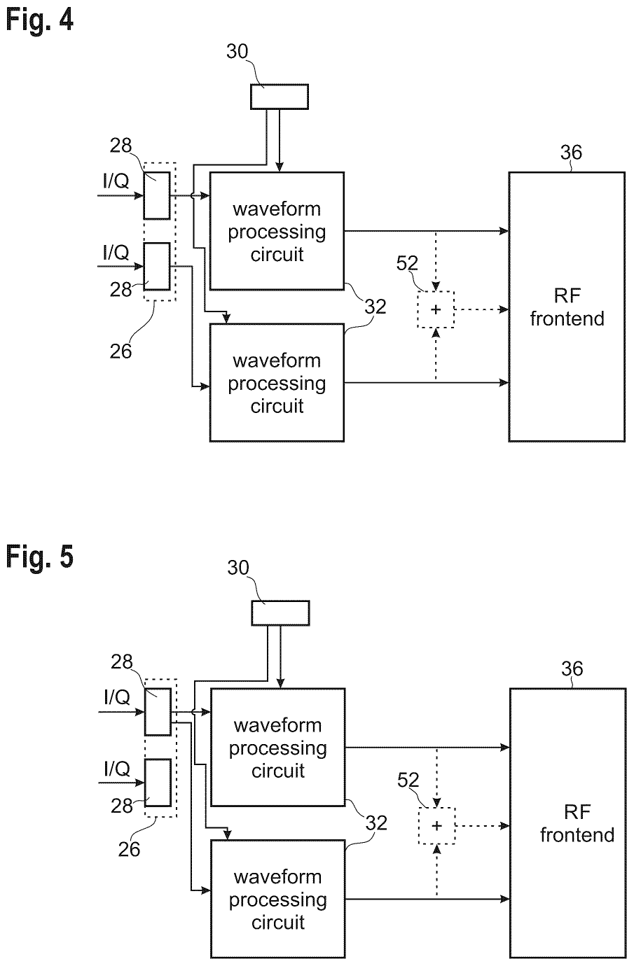

It is noted that, as is illustrated in FIG. 4, the test and/or measurement instrument 16 may comprise a plurality of waveform processing circuits 32 processing a plurality of waveform data streams in parallel, such that a plurality of modified waveform data streams are obtained. Therein, different waveform data streams may be modified based on the same control command signal, or independent of each other based on different control command signals. The different modified waveform data streams may be output individually or may, alternatively or additionally, be summed by a summation circuit 52.

According to another embodiment shown in FIG. 5, a single waveform data stream may be separated into a plurality of waveform data subs-streams. Therein, each waveform data sub-stream may have a bandwidth being a sub-band of the bandwidth of the original waveform data stream.

In an embodiment, the different waveform data sub-streams may be modified based on the same control command signal, or independent of each other based on different control command signals, thereby obtaining a plurality of modified waveform data sub-streams. The different modified waveform data streams may be output individually or may, alternatively or additionally, be summed by the summation circuit 52.

It is noted that, of course, an analysis of an output signal generated by the device under test 22 in response to the at least one RF transmission signal applied to the device under test 22 may be performed in order to analyze a performance of the device under test 22, namely by a corresponding analysis circuit and/or a corresponding measurement instrument, for example by one of the test and/or measurement instruments 16.

However, the corresponding analysis circuits are not shown in the FIGURES in order to enhance the visual clarity of the signal chain generating the RF transmission signal(s).

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a graphics processing unit (GPU), a digital signal processor (DSP), an application-specific integrated circuit (ASIC), a field programmable gate array (FPGA), a system on a chip (SoC), or the like, or any combinations thereof, and can include discrete digital or analog circuit elements or electronics, or combinations thereof. In an embodiment, circuitry includes hardware circuit implementations (e.g., implementations in analog circuitry, implementations in digital circuitry, and the like, and combinations thereof).

In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like.

For example, the functionality described herein can be implemented by special purpose hardware-based computer systems or circuits, etc., or combinations of special purpose hardware and computer instructions. Each of these special purpose hardware-based computer systems or circuits, etc., or combinations of special purpose hardware circuits and computer instructions form specifically configured circuits, machines, apparatus, devices, etc., capable of implementing the functionality described herein.

Of course, in an embodiment, two or more of these components, or parts thereof, can be integrated or share hardware and/or software, circuitry, etc. In an embodiment, these components, or parts thereof, may be grouped in a single location or distributed over a wide area. In circumstances where the components are distributed, the components are accessible to each other via communication links.

In an embodiment, one or more of the components of the system 10 referenced above include circuitry programmed to carry out one or more steps, actions or operations disclosed herein. In an embodiment, one or more computer-readable media associated with or accessible by such circuitry contains computer readable instructions embodied thereon that, when executed by such circuitry, cause the component or circuity to perform one or more steps, actions or operations disclosed herein.

In an embodiment, the computer readable instructions includes applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably).

In an embodiment, computer-readable media is any medium that stores computer readable instructions, or other information non-transitorily and is directly or indirectly accessible by a computing device, such as processor circuitry, etc., or other circuity disclosed herein etc. In other words, a computer-readable medium is a non-transitory memory at which one or more computing devices can access instructions, codes, data, or other information. As a non-limiting example, a computer-readable medium may include a volatile random access memory (RAM), a persistent data store such as a hard disk drive or a solid-state drive, or a combination thereof. In an embodiment, memory can be integrated with a processor, separate from a processor, or external to a computing system.

Accordingly, blocks of the block diagrams and/or flowchart illustrations support various combinations for performing the specified functions, combinations of operations for performing the specified functions and program instructions for performing the specified functions. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the steps, actions or operations disclosed herein. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

It will be appreciated that in one or more embodiments, the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), a graphics processing unit (GPU) or the like, or any combinations thereof.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

Although the method and various embodiments thereof have been described as performing sequential steps, the claimed subject matter is not intended to be so limited. As nonlimiting examples, the described steps need not be performed in the described sequence and/or not all steps are required to perform the method. Moreover, embodiments are contemplated in which various steps are performed in parallel, in series, and/or a combination thereof. As such, one of ordinary skill will appreciate that such examples are within the scope of the claimed embodiments.

In the detailed description herein, references to “one embodiment”, “an embodiment”, “an example embodiment”, “one or more embodiments”, “some embodiments”, etc., indicate that the embodiment or embodiments described may include a particular feature, structure, or characteristic, but every embodiment may not necessarily include the particular feature, structure, or characteristic. Moreover, such phrases are not necessarily referring to the same embodiment or embodiments. In addition, when a particular feature, structure, or characteristic is described in connection with an embodiment or embodiments, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

Where a range of values is provided, it is understood that each intervening value, to the tenth of the unit of the lower limit (unless the context clearly dictates otherwise), between the upper and lower limit of that range, and any other stated or intervening value in that stated range, is encompassed within the disclosure. The upper and lower limits of these smaller ranges may independently be included in the smaller ranges and are also encompassed within the disclosure, subject to any specifically excluded limit in the stated range. While the stated range includes one or both of the limits, ranges excluding either or both of those included limits are also included in the disclosure

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A signal generator system for generating a radio frequency, RF, signal,
wherein the signal generator system comprises at least one data input, at least one control input, and a waveform processing circuit,
wherein the at least one data input is configured to receive at least one waveform data stream, the at least one waveform data stream comprising information on a waveform to be generated,
wherein the at least one control input is configured to receive at least one control command signal, the control command signal comprising control information for modifying the data stream,
wherein the at least one waveform processing circuit is configured to modify the at least one waveform data stream based on the control command signal, thereby obtaining at least one modified waveform data stream.

2. The signal generator system of claim 1, wherein the waveform data stream is an IQ-data stream.

3. The signal generator system of claim 1, further comprising least one RF frontend, wherein the at least one RF frontend is configured to generate at least one RF transmission signal based on the at least one modified waveform data stream.

4. The signal generator system of claim 3, further comprising an RF output interface, wherein the RF output interface is connectable to at least one RF antenna and/or to a device under test.

5. The signal generator system of claim 1, further comprising at least one sample memory being connected to the at least one data input, wherein the at least one sample memory is configured to store the waveform data stream received via the data input.

6. The signal generator system of claim 1, wherein the signal generator system is configured to generate at least two different modified waveform data streams.

7. The signal generator system of claim 6, wherein the signal generator system is configured to generate the at least two different modified waveform data streams independent of each other.

8. The signal generator system of claim 6, wherein the at least two different modified waveform data streams correspond to the same waveform data stream.

9. The signal generator system of claim 6, wherein the at least two different modified waveform data streams correspond to different waveform data streams.

10. The signal generator system of claim 1, wherein the at least one waveform data stream comprises a recorded waveform.

11. The signal generator system of claim 1, wherein the at least one data input comprises at least one Ethernet port.

12. The signal generator system of claim 11, wherein the at least one data input is configured to receive the at least one waveform data stream via an Ethernet UDP stack.

13. The signal generator system of claim 1, wherein the at least one waveform data stream has a first bandwidth, wherein the at least one waveform processing circuit is configured to separate the at least one waveform data stream into a plurality of waveform data sub-streams, wherein each waveform data sub-stream has a bandwidth being a sub-band of the first bandwidth.

14. The signal generator system of claim 1, wherein the at least one waveform processing circuit is configured to separate the at least one waveform data stream into a plurality of waveform data sub-streams, wherein the at least one waveform processing circuit is configured to generate a plurality of modified waveform data streams based on the plurality of waveform data sub-streams.

15. The signal generator system of claim 14, further comprising a plurality of RF outputs, wherein the signal generator system is configured to output a plurality of RF transmission signals corresponding to the plurality of modified waveform data streams via the plurality of RF outputs.

16. The signal generator system of claim 14, further comprising a summation circuit, wherein the summation circuit is configured to sum at least two of the plurality of modified waveform data streams.

17. The signal generator system of claim 1, wherein the waveform data stream comprises at least one fading parameter.

18. The signal generator system of claim 1, wherein the control command signal corresponds to a predefined test scenario for a device under test.

19. The signal generator system of claim 18, wherein the predefined test scenario comprises at least one of a radar test, an angle of arrival system test, or a phased antenna array test.

20. The signal generator system of claim 1, wherein the control command signal comprises information on at least one of frequency changes to be applied to the at least one waveform data stream, amplitude changes to be applied to the at least one waveform data stream, or phase changes to be applied to the at least one waveform data stream.
